(19) United States
(12) Patent Application Publication
(10) Pub. No.: US 2025/0081659 A1
(43) Pub. Date: Mar. 6, 2025

(54) METHOD FOR PASSIVATING PHOTOVOLTAIC CELLS

(71) Applicant: COMMISSARIAT A L'ENERGIE ATOMIQUE ET AUX ENERGIES ALTERNATIVES, PARIS (FR)

(72) Inventors: Samuel HARRISON, GRENOBLE CEDEX (FR); Mickaël ALBARIC, GRENOBLE CEDEX (FR); Benoît MARTEL, GRENOBLE CEDEX (FR)

(21) Appl. No.: 18/824,333

(22) Filed: Sep. 4, 2024

(30) Foreign Application Priority Data
Sep. 5, 2023 (FR) 2309302

(51) Int. Cl. H01L 31/18; H01L 31/05

(52) U.S. Cl. CPC H10F 71/129; H10F 19/90

(57) ABSTRACT

A method for passivating photovoltaic cells includes providing a plurality of cells, each cell including a front face, a rear face and a peripheral edge, each cell being provided with a plurality of first tracks and a plurality of second tracks being parallel, stacking the cells, the plurality of first tracks and the plurality of second tracks of each cell being positioned between the cell concerned and an adjacent cell, and depositing a passivation layer onto the peripheral edge of the cells by injecting a passivation species, the plurality of first tracks and the plurality of second tracks forming a penetration barrier to the passivation species.

### CROSS-REFERENCE TO RELATED APPLICATIONS

This application claims priority to French Patent Application No. 2309302, filed Sep. 5, 2023, the entire content of which is incorporated herein by reference in its entirety.

### FIELD

This invention generally relates to the manufacture of photovoltaic cells.

The invention more particularly relates to a method for passivating photovoltaic cells.

### BACKGROUND

A photovoltaic module comprises a multitude of identical photovoltaic cells connected in series and/or parallel to output the voltage and/or current required to power electric devices. The most common module format employs 60 square (or “pseudo-square”) cells, 156 mm on a side, distributed into six strings of ten cells connected in series. The six strings of photovoltaic cells are also connected in series. The open-circuit voltage across the module is then equal to 60 times the threshold voltage of a photovoltaic cell. The electric current of the module corresponds approximately to the current provided by each photovoltaic cell (in practice, the photovoltaic cells do not have exactly the same performance and the electric current is limited by the least efficient cell in the module).

With the latest photovoltaic cell technologies, especially PERT (Passivated Emitter and Rear Totally diffused) technology, the current of a monofacial cell with a 156 mm×156 mm surface area reaches high values, in the order of 9 A for solar irradiance of 1000 W/m². These current values are increased by about 20% when a bifacial cell is used, due to the diffuse solar radiation captured on the rear face of the cell. This high electric current circulates in the interconnection elements between the cells in the module and causes significant resistive losses.

In order to reduce these resistive losses, one solution is to assemble modules with photovoltaic cells with a smaller surface area, and therefore lower current. These cells with a lower surface area are commonly called “sub-cells” and are obtained by cutting full-size photovoltaic cells (for example, 156 mm×156 mm).

However, cutting a photovoltaic cell creates new edges that are bare. In addition, cutting (with a laser, for example) is likely to create defects and insert impurities in proximity to the cutting plane. These defects and impurities decrease the lifetime of the free charge carriers by acting as recombination centres for electron-hole pairs, resulting in a reduction in the cell's efficiency. This phenomenon is particularly pronounced for heterojunction (HET) photovoltaic cells, which by nature have very few surface defects and where the creation of a few localised defects is enough to significantly reduce the cell's electrical performance.

It is especially known from document FR3091025 a method for passivating photovoltaic cells making it possible to localise the deposition of a passivation material in the vicinity of one edge of the photovoltaic cell only.

To be compatible with the requirements of industrial production, while depositing a passivation material only onto the edges of the photovoltaic cells, document FR3091025 describes an arrangement consisting in stacking a plurality of photovoltaic cells on one another, the stack resting directly on a support.

According to this arrangement, the front and rear faces of each photovoltaic cell are therefore in direct contact with one of the faces of another photovoltaic cell or with the support. This direct contact leads to the risk of degrading these front and rear faces, and in particular the metallisation present on these front and/or rear faces. This then results in degrading electrical performance.

Furthermore, with this arrangement, there is a risk of the passivation layer being deposited onto the metallisations, which induces additional local resistance. This passivation layer formed on the metallisations then prevents the passage of electric charges between the photovoltaic cells in a photovoltaic module.

### SUMMARY

An aspect of the present invention is therefore to improve manufacture of photovoltaic cells by especially ensuring that the process for passivating the photovoltaic cells does not degrade the photovoltaic cells themselves, and in particular metallisations of these photovoltaic cells, or the electrical performance associated therewith.

An aspect of the invention then relates firstly to a method for passivating photovoltaic cells comprising steps of:
providing a plurality of photovoltaic cells, each photovoltaic cell comprising a front face, intended to be exposed to incident radiation, a rear face opposite to the front face and a peripheral edge connecting the front face and the rear face, each photovoltaic cell being provided, on the front face or the rear face, with a plurality of first interconnection conductor tracks and a plurality of second interconnection conductor tracks, the plurality of second interconnection conductor tracks extending in parallel to the plurality of first interconnection conductor tracks, a plurality of pairs of interconnection conductor tracks being formed, each pair of interconnection conductor tracks comprising a first interconnection conductor track from the plurality of first interconnection conductor tracks and a second interconnection conductor track from the plurality of second interconnection conductor tracks,
stacking the plurality of photovoltaic cells, the plurality of first interconnection conductor tracks and the plurality of second interconnection conductor tracks of each photovoltaic cell being positioned between the photovoltaic cell concerned and an adjacent photovoltaic cell in such a way that the face of the photovoltaic cell provided with the plurality of first interconnection conductor tracks and the plurality of second interconnection conductor tracks is positioned at a distance from the face of the adjacent photovoltaic cell facing the face of the photovoltaic cell provided with the plurality of first interconnection conductor tracks and the plurality of second interconnection conductor tracks, and
depositing a passivation layer onto the peripheral edge of the photovoltaic cells of the plurality of photovoltaic cells by injecting at least one passivation species.

Thus, beneficially according to an aspect of the invention, the use of electrically conductive interconnection tracks makes it possible to stack photovoltaic cells without the front and rear faces of each photovoltaic cell being in direct contact. This avoids degrading electrical performance.

In addition, by virtue of the configuration involving the formation of pairs of busbars positioned between the adjacent photovoltaic cells, the surface of the interconnection conductor tracks is not exposed to the passivation species (the latter is therefore not deposited onto the surface of the interconnection conductor tracks). The surface of the interconnection conductor tracks is therefore protected. This therefore improves the interconnection between photovoltaic cells when forming photovoltaic modules.

This absence of a layer of passivation species on the interconnection conductor tracks also makes it possible to guarantee the quality of the interconnection between the photovoltaic cells (no additional local resistance, which could be induced by the presence of this layer of passivation species on the interconnection conductor tracks, is added). The conductive glue for assembling the photovoltaic cells is positioned directly on the surface of the interconnection conductor tracks, thus facilitating the passage of electric charges between the photovoltaic cells of the photovoltaic module concerned.

Finally, by virtue of the positioning of the plurality of first interconnection conductor tracks and the plurality of second interconnection conductor tracks, when the photovoltaic cells are stacked, only the portions of the peripheral edge parallel to the interconnection conductor tracks of each photovoltaic cell are visible and accessible from the outside of the stack. In other words, along these portions of the peripheral edge, the interconnection conductor tracks (and in particular the interconnection conductor tracks closest to these portions of the peripheral edge) isolate the core of each photovoltaic cell from the outside of the stack. This then ensures that, along these portions, only the peripheral edge of the photovoltaic cells and a small surface of the front and rear faces (at the portions of the peripheral edge transverse to the interconnection conductor tracks) is exposed to the passivation species for deposition of the passivation layer.

Further to the characteristics just discussed in the previous paragraphs, the passivation method according to one or more aspects of the invention may have one or more additional characteristics from among the following, considered individually or according to any technically possible combinations:
for each pair of interconnection conductor tracks, the first interconnection conductor track from the plurality of first interconnection conductor tracks and the second interconnection conductor track from the plurality of second interconnection conductor tracks are spaced apart by a predetermined distance of less than 100 micrometres;
during the stacking step, the photovoltaic cells are positioned in such a way that the plurality of first interconnection conductor tracks and the plurality of second interconnection conductor tracks are in direct contact with the face of the adjacent photovoltaic cell facing the face of the photovoltaic cell provided with the plurality of first interconnection conductor tracks and the plurality of second interconnection conductor tracks;
each photovoltaic cell of the plurality of photovoltaic cells comprises a plurality of electrodes positioned transversally to the plurality of first interconnection conductor tracks and the plurality of second interconnection conductor tracks, each first interconnection conductor track from the plurality of first interconnection conductor tracks and each second interconnection conductor track from the plurality of second interconnection conductor tracks having a width greater than or equal to the width of each electrode of the plurality of electrodes;
each photovoltaic cell also comprises a plurality of third interconnection conductor tracks, the plurality of third interconnection conductor tracks being formed on the face opposite to the face provided with the plurality of first interconnection conductor tracks and the plurality of second interconnection conductor tracks;
during the stacking step, the photovoltaic cells are positioned such that each third interconnection conductor track from the plurality of third interconnection conductor tracks of a photovoltaic cell is placed between a first interconnection conductor track and a second interconnection conductor track of a corresponding pair of interconnection conductor tracks of the adjacent photovoltaic cell, each third interconnection conductor track being in direct contact with the face of the adjacent photovoltaic cell on which the first interconnection conductor track concerned and the second interconnection conductor track concerned are formed; and
each photovoltaic cell also comprises a plurality of fourth interconnection conductor tracks and a plurality of fifth interconnection conductor tracks, the plurality of fifth interconnection conductor tracks extending in parallel to the plurality of fourth interconnection conductor tracks, the plurality of fourth interconnection conductor tracks and the plurality of fifth interconnection conductor tracks being formed on the face opposite to the face provided with the plurality of first interconnection conductor tracks and the plurality of second interconnection conductor tracks, the plurality of fourth interconnection conductor tracks being positioned facing the plurality of first interconnection conductor tracks and the plurality of fifth interconnection conductor tracks being positioned facing the plurality of second interconnection conductor tracks.

An aspect of the invention also relates to a method for passivating photovoltaic cells comprising steps of:
providing a plurality of photovoltaic cells, each photovoltaic cell comprising a front face, intended to be exposed to incident radiation, a rear face opposite to the front face and a peripheral edge connecting the front face and the rear face, each photovoltaic cell being provided, on the front face, with a first interconnection conductor track positioned in parallel to a first portion of the peripheral edge, each photovoltaic cell being provided, on the rear face, with a second interconnection conductor track positioned in parallel to a second portion of the peripheral edge, the first portion of the peripheral edge and the second portion of the peripheral edge being parallel to each other,
stacking the plurality of photovoltaic cells, the first interconnection conductor track and the second interconnection conductor track of each photovoltaic cell being positioned between the photovoltaic cell concerned and an adjacent photovoltaic cell in such a way that the front face of the photovoltaic cell provided with the first interconnection conductor track is positioned at a distance from the rear face of the adjacent photovoltaic cell provided with the second interconnection conductor track, and
depositing a passivation layer onto the peripheral edge of the photovoltaic cells of the plurality of photovoltaic cells by injecting at least one passivation species, the first interconnection conductor track and the second interconnection conductor track forming a penetration barrier to the passivation species so that the passivation layer covers the peripheral edge of each photovoltaic cell.

This configuration is particularly beneficial because it enables the photovoltaic cells to be stacked without the front and rear faces of each photovoltaic cell being subjected to stress. This avoids degrading electrical performance.

In addition, by virtue of the configuration involving busbars positioned between the adjacent photovoltaic cells, the surface of the interconnection conductor tracks is not exposed to the passivation species (the latter is therefore not deposited onto the surface of the interconnection conductor tracks). The surface of the interconnection conductor tracks is therefore protected. This therefore improves the interconnection between photovoltaic cells when forming photovoltaic modules.

This passivation method is particularly adapted to sub-cells with a smaller surface area.

Further to the characteristics just discussed in the previous paragraphs, the passivation method according to one or more aspects of the invention may have one or more additional characteristics from among the following, considered individually or according to any technically possible combinations:
during the stacking step, the photovoltaic cells are positioned in such a way that the first interconnection conductor track and the second interconnection conductor track are in direct contact with the face of the adjacent photovoltaic cell facing the face of the photovoltaic cell provided with the first interconnection conductor track and the second interconnection conductor track;
each photovoltaic cell comprises a third interconnection conductor track and a fourth interconnection conductor track, the third interconnection conductor track being formed on the front face provided with the first interconnection conductor track, in parallel with the first interconnection conductor track, the fourth interconnection conductor track being formed on the rear face provided with the second interconnection conductor track, in parallel with the second interconnection conductor track, the third interconnection conductor track being formed at a predetermined distance from the first interconnection conductor track and the fourth interconnection conductor track being formed at said predetermined distance from the second interconnection conductor track; and
the predetermined distance is less than 100 micrometres.

### BRIEF DESCRIPTION OF THE FIGURES

Further characteristics and benefits of the invention will become clear from the description given below, by way of indicating and in no way limiting purposes, with reference to the appended figures, among which:

FIG. 1 is a top view of a photovoltaic cell according to a first example of a first embodiment of a passivation method according to the invention,

FIG. 2 is a cross-section view of a stack comprising the photovoltaic cell of FIG. 1,

FIG. 3 represents a cross-section view of a photovoltaic cell according to a second example of the first embodiment of the passivation method according to the invention,

FIG. 4 is a cross-section view of a stack comprising the photovoltaic cell of FIG. 3,

FIG. 5 represents a cross-section view of a photovoltaic cell according to a third example of the first embodiment of the passivation method according to the invention,

FIG. 6 is a cross-section view of a stack comprising the photovoltaic cell of FIG. 5,

FIG. 7 represents a cross-section view of a photovoltaic cell according to a first example of a second embodiment of the passivation method according to the invention,

FIG. 8 is a cross-section view of a stack comprising the photovoltaic cell of FIG. 7,

FIG. 9 represents a cross-section view of a photovoltaic cell according to a second example of the second embodiment of the passivation method in accordance with the invention, and

FIG. 10 is a cross-section view of a stack comprising the photovoltaic cell of FIG. 9.

For the purpose of clarity, identical or similar elements are identified by identical reference signs throughout the figures.

### DETAILED DESCRIPTION

An aspect of this invention is to improve manufacture of photovoltaic cells and in particular to improve the passivation phase of photovoltaic cells.

The photovoltaic cells 5; 6 concerned by one or more aspects of the present invention are, for example, full-size cells 5 or sub-cells 6, that is portions or pieces of a full-size photovoltaic cell (also referred to as a “whole” photovoltaic cell).

The surface area of the sub-cells 6 is smaller than that of the full-size photovoltaic cells 5. For example, the sub-cells 6 have a format commonly known as “shingle” (or “half-cell”). These sub-cells 6 are, for example, obtained beforehand by cutting full-size photovoltaic cells.

The full-size photovoltaic cells 5 have been previously manufactured from semiconductor substrates, for example of crystalline silicon. These substrates have initially been cut from a silicon ingot and then subjected to several manufacturing steps (for example surface structuring, doping, annealing, passivation, screen printing, etc. steps), but no further cutting steps. The full-size photovoltaic cells 5 have passivation layers on all their faces and side surfaces.

The photovoltaic cells 5; 6 concerned by one or more aspects of the present invention each comprise a first face 5A; 6A and a second face 5B; 6B, opposite to the first face 5A; 6A. The first face 5A; 6A is, for example, the face intended to be exposed to incident solar radiation. In this case, the first face 5A; 6A corresponds to the front face 5A; 6A of the photovoltaic cell 5; 6 concerned. The remainder of this description is based on this example, considering, for each photovoltaic cell 5; 6, the front face 5A; 6A (exposed to incident solar radiation) and the rear face 5B; 6B (opposite to the front face 5A; 6A).

Each photovoltaic cell 5; 6 also comprises a peripheral edge 5C; 6C connecting the front face 5A; 6A and the rear face 5B; 6B. This peripheral edge 5C; 6C therefore corresponds to the side surface connecting the front face 5A; 6A and the rear face 5B; 6B. By definition here, the peripheral edge 5C; 6C therefore extends on the entire perimeter of the front face 5A; 6A and the rear face 5B; 6B of the photovoltaic cell 5; 6. In the present description, it is meant by “perimeter” of the photovoltaic cell 5; 6, the contour line of the front face 5A; 6A and/or of the rear face 5B; 6B.

Viewed from the front (from the front face 5A; 6A or the rear face 5B; 6B), the photovoltaic cells 5; 6 have, in an embodiment, a rectangular or pseudo-rectangular shape. In the pseudo-rectangular format, the four corners of the photovoltaic cells 5; 6 are truncated or rounded. In particular, the photovoltaic cells 5; 6 can have a square or pseudo-square shape.

The perimeter of the photovoltaic cell 5; 6 therefore has here a rectangular or pseudo-rectangular shape (or, in the particular case, a square or pseudo-square shape).

Given the shape of the photovoltaic cell 5; 6, the peripheral edge 5C; 6C then has four portions 5C1, 5C2, 5C3, 5C4; 6C1, 6C2, 6C3, 6C4 enabling the rectangular or pseudo-rectangular (or, in the particular case, square or pseudo-square) shape to be defined. The portions 5C1, 5C2, 5C3, 5C4; 6C1, 6C2, 6C3, 6C4 of the peripheral edge 5C; 6C are therefore parallel two by two.

The dimensions of the front face 5A; 6A and the rear face 5B; 6B are generally standardised, for example 156 mm×156 mm. In the case of sub-cells (from cutting a full-size photovoltaic cell), these dimensions are in the order of 156 mm x 78 mm, for example.

Photovoltaic cells 5; 6 can be monofacial or bifacial cells. In the case of a monofacial cell, only the front face 5A; 6A of the photovoltaic cell 5; 6 captures solar radiation. In the case of a bifacial cell, both faces 5A, 5B; 6A, 6B of the photovoltaic cell 5; 6 capture solar radiation. The front face 5A; 6A is then the one that enables the maximum electric current to be obtained when facing the sun.

In an embodiment, the photovoltaic cells 5; 6 are ready to be interconnected into a string of cells. They are provided on the front face 5A; 6A and/or on the rear face 5B; 6B with one or more metallisation elements 7, 8A, 8B, 9A, 9B, 10A, 10B, 11A, 11B, 11C, 12A, 12B, 12C, 13A, 13B, 13C; 20A, 20B, 22A, 22B (also called “metallisations”) intended to collect the photogenerated charge carriers and to receive interconnection elements, for example metal wires or stripes.

The metallisations 7, 8A, 8B, 9A, 9B, 10A, 10B, 11A, 11B, 11C, 12A, 12B, 12C, 13A, 13B, 13C; 20A, 20B, 22A, 22B are here an array of electrodes 7 (also called “collection fingers 7”) and interconnection electrically conductor tracks 8A, 8B, 9A, 9B, 10A, 10B, 11A, 11B, 11C, 12A, 12B, 12C, 13A, 13B, 13C; 20A, 20B, 22A, 22B referred to hereinafter as “busbars” (these interconnection electrically conductor tracks are also known as “transmission bars”). The busbars 8A, 8B, 9A, 9B, 10A, 10B, 11A, 11B, 11C, 12A, 12B, 12C, 13A, 13B, 13C; 20A, 20B, 22A, 22B can electrically connect collection fingers 7 distributed over the entire surface area of the front face 5A; 6A and/or the rear face 5B; 6B. The rear face 5B; 6B of the photovoltaic cells 5; 6 can also be entirely metallised.

The electrodes forming the collection fingers 7 are for example deposited onto the front face 5A; 6A of the photovoltaic cell 5; 6. These collection fingers 7 generally extend in parallel to each other along the front face 5A; 6A of each photovoltaic cell 5; 6. They are here uniformly distributed over the front face 5A; 6A of each photovoltaic cell 5; 6.

The collection fingers 7 are narrow, that is they have a width of less than 100 micrometres (μm), for example. The width is, in an embodiment, less than 50 μm. They have a height of a few tens of micrometres. In an embodiment, this height is less than 30 μm. In an embodiment, this height is between 10 and 20 μm.

They are generally formed by screen-printing a paste containing silver, copper or aluminium. Alternatively, they can be formed by inkjet or plating deposition.

The rear face 5B; 6B of the photovoltaic cell 5; 6 is either covered with another array of electrodes (in the case of bifacial cells) or with a solid metal layer, for example of aluminium (in the case of monofacial cells).

In order to transport the electric current in a photovoltaic string comprising several interconnected photovoltaic cells, the collection fingers 7 are connected to each other by busbars 8A, 8B, 9A, 9B, 10A, 10B, 11A, 11B, 11C, 12A, 12B, 12C, 13A, 13B, 13C; 20A, 20B, 22A, 22B. These busbars 8A, 8B, 9A, 9B, 10A, 10B, 11A, 11B, 11C, 12A, 12B, 12C, 13A, 13B, 13C; 20A, 20B, 22A, 22B are generally formed at the same time as the collection fingers 7. The busbars 8A, 8B, 9A, 9B, 10A, 10B, 11A, 11B, 11C, 12A, 12B, 12C, 13A, 13B, 13C; 20A, 20B, 22A, 22B are for example also formed by screen printing a paste containing silver, copper or aluminium. Alternatively, they can be formed by inkjet or plating deposition.

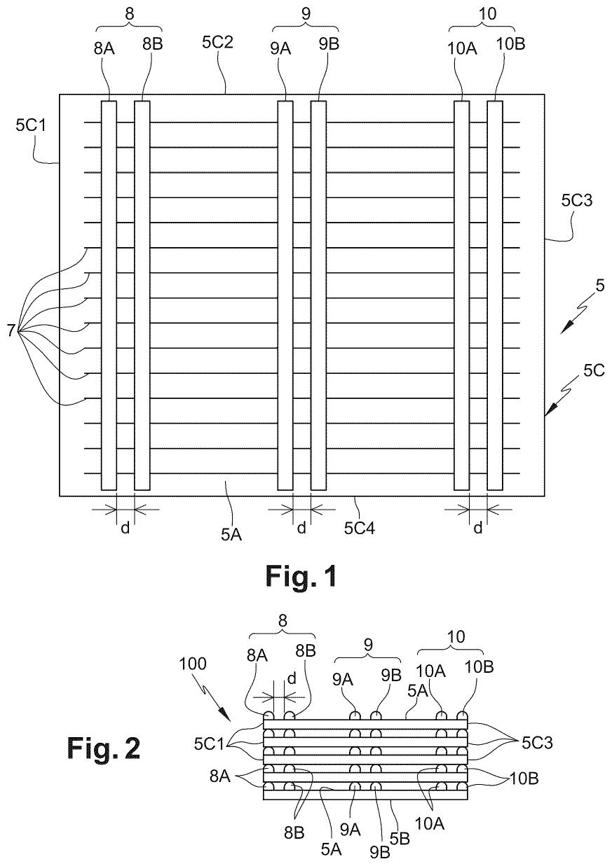

As is visible for example in FIG. 1, the busbars 8A, 8B, 9A, 9B, 10A, 10B electrically connect the collection fingers 7 and are oriented perpendicularly to the collection fingers 7. Here, the busbars extend in parallel to a first portion 5C1; 6C1 and a second portion 5C3; 6C3 of the peripheral edge 50; 6C.

The (full-size) photovoltaic cell 5 schematically represented in FIG. 1 here comprises a plurality of first busbars 8A, 9A, 10A and a plurality of second busbars 8B, 9B, 10B formed on its front face 5A, extending perpendicularly to the plurality of collection fingers 7 represented. Here, each of the plurality of first busbars 8A, 9A, 10A and the plurality of second busbars 8B, 9B, 10B comprises three distinct busbars. In an embodiment, each of the plurality of first busbars 8A, 9A, 10A and the plurality of second busbars 8B, 9B, 10B comprises between 6 and 10 busbars.

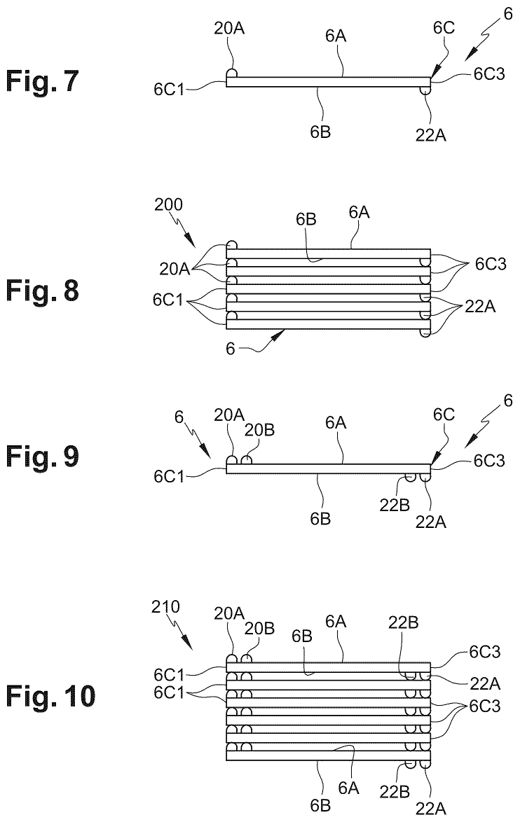

The photovoltaic cell 6 represented in FIGS. 7 and 8 corresponds to a sub-cell obtained by cutting a whole photovoltaic cell. In this example, the sub-cell 6 is provided with a first busbar 20A on its front face 6A and a second busbar 22A on its rear face 6B.

Each busbar 8A, 8B, 9A, 9B, 10A, 10B, 11A, 11B, 11C, 12A, 12B, 12C, 13A, 13B, 13C; 20A, 20B, 22A, 22B has a width greater than or equal to the width of each collection finger 7. The width of each busbar is, for example, less than a few hundred micrometres, for example less than 500 μm. In an embodiment, the width of each busbar 8A, 8B, 9A, 9B, 10A, 10B, 11A, 11B, 11C, 12A, 12B, 12C, 13A, 13B, 13C; 20A, 20B, 22A, 22B is between 50 and 300 μm.

Each busbar 8A, 8B, 9A, 9B, 10A, 10B, 11A, 11B, 11C, 12A, 12B, 12C, 13A, 13B, 13C; 20A, 20B, 22A, 22B has a height greater than or equal to the height of each collection finger 7. The height of each busbar 8A, 8B, 9A, 9B, 10A, 10B, 11A, 11B, 11C, 12A, 12B, 12C, 13A, 13B, 13C; 20A, 20B, 22A, 22B is here less than 50 μm. In an embodiment, it is between 20 and 30 μm.

The number of busbars formed on each face of the photovoltaic cells is of course not limited to the examples set forth in the figures.

As the photovoltaic cells 5; 6 are obtained, for example, by cutting a full-size photovoltaic cell, the faces of which are provided with passivation layers, the front face 5A; 6A and the rear face 5B; 6B of each photovoltaic cell 5; 6 have a passivation layer. This passivation layer renders the surface defects of the photovoltaic cell 5; 6 inactive and improves the lifetime of the photogenerated charge carriers.

On the other hand, the peripheral edge 5C; 6C of the photovoltaic cell 5; 6 comprises zones where the semiconductor material (that is, silicon) has been bared. In other words, these zones of the peripheral edge 5C; 6C are devoid of a passivation layer (due to cutting), unlike the front face 5A; 6A, the rear face 5B; 6B and the (possible) other zones of the peripheral edge 5C; 6C of the photovoltaic cell 5; 6. For example, when a full-size photovoltaic cell is cut into four parallel cell strips, two cell strips have two non-passivated parallel edges, and two other cell strips have a single non-passivated edge.

Here, for example, cutting is made along a direction parallel to the busbars present on the photovoltaic cells. In this case, the bared edges extend in parallel to the busbars.

The photovoltaic cells 5 concerned may also be full-size cells on which part of the peripheral edge 5C has been subjected to abrasion. This is the case, for example, when a junction opening is implemented to avoid possible short circuits. In this case, the peripheral edge 5C of the photovoltaic cell 5 also has a non-passivated part on its peripheral edge 5C.

An aspect of this invention is therefore to protect these zones, in which the semiconductor material is bared, by forming a passivation layer, while also protecting the surface of the busbars (which make it possible to make the electrical connection between the photovoltaic cells).

For this, an aspect of the present invention relates to a method for passivating photovoltaic cells 5; 6 so as to form a passivation layer on part of each of the photovoltaic cells 5; 6.

FIGS. 1 to 6 are associated with a first embodiment of this passivation method in accordance with the invention. These figures relate to several examples of implementation of this first embodiment. These figures relate generally to full-size photovoltaic cells 5.

FIGS. 7 to 10 are associated with a second embodiment of the passivation method in accordance with the invention. Examples of implementation of this second embodiment are represented. These figures relate generally to photovoltaic cells 6 known as sub-cells (that is, obtained by cutting a full-size photovoltaic cell).

It is to be noted that, prior to implementation of the passivation method (whatever the embodiment considered), the photovoltaic cells 5; 6 have been manufactured from semiconductor substrates (crystalline silicon, for example). They have also, for example, been cut or subjected to abrasion of part of their peripheral edge after manufacture thereof.

In the first embodiment, each photovoltaic cell 5 considered is provided, on one of its faces 5A, 5B (here on the front face 5A), with a plurality of first busbars 8A, 9A, 10A and a plurality of second busbars 8B, 9B, 10B (as is visible in FIGS. 1 and 2).

As previously defined, the first busbars 8A, 9A, 10A extend in parallel to each other and the second busbars 8B, 9B, 10B extend in parallel to each other. Thus, all the busbars of the plurality of first busbars and the plurality of second busbars extend in parallel to each other. Here, they extend in parallel to the first portion 5C1 and the third portion 5C3 of the peripheral edge 5C.

As is visible in FIGS. 1 and 2, a plurality of pairs 8, 9, 10 of busbars are formed. Each pair 8, 9, 10 of busbars comprises a first busbar 8A, 9A, 10A from the plurality of first busbars and a second busbar 8B, 9B, 10B from the plurality of second busbars.

In practice, each second busbar 8B, 9B, 10B of the plurality of second busbars is formed at a predetermined distance d from the corresponding first busbar 8A, 9A, 10A of the plurality of first busbars. In other words, in each pair 8, 9, 10 of busbars, the second busbar 8B, 9B, 10B is positioned at a distance (and at the same distance) from the first busbar 8A, 9A, 10A.

Beneficially according to an embodiment of the invention, the predetermined distance is, for example, in the order of the width of each busbar. In an embodiment, the predetermined distance is less than or equal to 100 μm. In an embodiment still, this predetermined distance is less than or equal to 50 μm. In other words, for each pair 8, 9, 10 of busbars, the second busbar 8B, 9B, 10B is positioned at a distance less than or equal to 100 μm (and in an embodiment 50 μm) from the first busbar 8A, 9A, 10A.

Thus, each photovoltaic cell 5 considered in the first embodiment of the passivation method comprises, at least on one of its faces 5A, 5B (here on the front face 5A), a plurality of first busbars and a plurality of second busbars. Compared with conventional photovoltaic cells, the photovoltaic cells 5 according to this first embodiment therefore comprise a group of additional busbars (here the plurality of second busbars) arranged so as to form pairs of busbars with the first busbars.

FIGS. 1 and 2 correspond to a first example of implementation of the passivation method.

This method firstly comprises a first step of providing a plurality of photovoltaic cells 5. During this step, all the photovoltaic cells 5 of the plurality of photovoltaic cells considered have the same shape and the same dimensions. Furthermore, as previously indicated, the photovoltaic cells 5 of the plurality of photovoltaic cells considered are all provided, on one of their faces (here on the front face 5A) with the plurality of first busbars 8A, 9A, 10A and the plurality of second busbars 8B, 9B, 10B.

In practice, these photovoltaic cells 5 (with the plurality of first busbars 8A, 9A, 10A and the plurality of second busbars 8B, 9B, 10B) are obtained, for example, from conventional photovoltaic cells (therefore with only the plurality of first busbars, for example). The plurality of second busbars 8B, 9B, 10B is then formed by adding the plurality of second busbars 8B, 9B, 10B to the face (here the front face 5A) comprising the plurality of first busbars 8A, 9A, 10A. This is implemented, for example, prior to the first step of providing the photovoltaic cells 5.

The passivation method then continues with a second step of stacking the plurality of photovoltaic cells 5 each provided with the plurality of first busbars 8A, 9A, 10A and the plurality of second busbars 8B, 9B, 10B (a stack 100 is visible in FIG. 2).

In this description, it is meant by “stacking” photovoltaic cells, the arrangement of these photovoltaic cells one after the other. Stacking photovoltaic cells therefore corresponds to forming a group of photovoltaic cells.

This stack 100 is for example implemented vertically: the photovoltaic cells 5 are then superimposed on one another (as represented in FIG. 2). Alternatively, the stack may be made horizontally. In this case, the photovoltaic cells are positioned one after the other.

In practice, this stack is, for example, implemented on a support (not represented) intended to be subsequently positioned in a thin film deposition enclosure (for the associated step described hereafter).

Beneficially according to an embodiment of the invention, each photovoltaic cell 5 is positioned so that the plurality of first busbars 8A, 9A, 10A and the plurality of second busbars 8B, 9B, 10B of the photovoltaic cell 5 concerned are placed between this photovoltaic cell 5 and the adjacent photovoltaic cell 5. In other words, in the stack 100, the photovoltaic cells 5 are arranged one after the other with the positioning of the plurality of first busbars 8A, 9A, 10A and the plurality of second busbars 8B, 9B, 10B between two adjacent photovoltaic cells 5.

This arrangement is implemented such that the front face 5A of the photovoltaic cell 5 provided with the plurality of first busbars 8A, 9A, 10A and the plurality of second busbars 8B, 9B, 10B is positioned at a distance from the rear face 5B of the adjacent photovoltaic cell 5. For the record, the photovoltaic cells 5 considered in this first example all have the same configuration with the plurality of first busbars 8A, 9A, 10A and the plurality of second busbars 8B, 9B, 10B formed on their front face 5A. The faces of the photovoltaic cells 5 are therefore not in contact with each other when stacked.

In this stacking step, the plurality of first busbars 8A, 9A, 10A and the plurality of second busbars 8B, 9B, 10B (of a photovoltaic cell 5) are therefore positioned in direct contact with the rear face 5B of the adjacent photovoltaic cell 5.

This configuration is particularly beneficial because it enables the photovoltaic cells 5 to be stacked without the front and rear faces of each photovoltaic cell 5 being subjected to stress. This avoids degrading electrical performance.

The passivation method then comprises a step of depositing a passivation layer onto part of the photovoltaic cells 5 stacked. For this, the stack 100 of photovoltaic cells 5 is placed, for example, in a thin film deposition enclosure (not represented in the figures).

The passivation layer is formed from at least one passivation species. In an embodiment, this passivation species is in the form of a gas. Deposition of the passivation layer is then implemented by injecting the passivation species into the deposition enclosure mentioned.

In practice, a passivation layer is formed, for example, by Atomic Layer Deposition (ALD). According to this method, different precursor gases are inserted into the thin film deposition enclosure and conveyed to the different zones (here the portions of the peripheral edge 5C of each photovoltaic cell 5) onto which one or more atomic layers are to be deposited.

In practice, an atomic layer is formed on a zone concerned (that is, here the peripheral edge 5C of each photovoltaic cell 5) by exposing this zone to the flow of a first precursor gas injected into the thin film deposition enclosure by injection means (not represented). This first precursor gas reacts with the terminations of the zone concerned and forms a monolayer containing other terminations (reactive groups). A second precursor gas (also injected by the injection means) then inserted reacts with the terminations of the monolayer formed (following injection of the first precursor gas) to form the desired passivation layer.

In practice, the injection means are formed, for example, by an injection head (not represented) enabling gas to be inserted into the thin film deposition enclosure. The deposition conditions (such as the position of the injection head, the flow rates of the gases, the concentration of the precursors and the temperature) and the dimensions of the injection head are beneficially chosen so that the passivation layer is formed, for example, at the first portion 5C1 and the second portion 5C3 of the peripheral edge 5C of each photovoltaic cell 5 of the stack 100.

In an embodiment, the material of the passivation layer is, for example, alumina (Al₂O₃), silicon dioxide (SiO₂), silicon nitride (Si₃N₄) or hydrogenated amorphous silicon (a-Siₓ:H).

The thickness of the passivation layer is in the order of a few nanometres (nm) to a few tens of nanometres. For example, in the case of alumina, the thickness of the passivation layer is greater than 5 nm, in an embodiment between 5 and 15 nm. In the case of hydrogenated amorphous silicon, the thickness of the passivation layer is in an embodiment between 5 and 15 nm.

Alternatively, the passivation species may be in the form of a vaporised liquid solution. It is, for example, a vaporised liquid polymer solution. The polymer here is a fluoropolymer such as Nafion™.

By virtue of the arrangement described previously (with the plurality of first busbars 8A, 9A, 10A and the plurality of second busbars 8B, 9B, 10B on the front face 5A of each photovoltaic cell 5 and stacking of the photovoltaic cells 5 one after the other with the positioning of the plurality of first busbars 8A, 9A, 10A and the plurality of second busbars 8B, 9B, 10B between two adjacent photovoltaic cells 5), the photovoltaic cells 5 are stacked on one another without contact between the faces of the photovoltaic cells.

In addition, as the contact between the photovoltaic cells is made at the surface of the first and second busbars, the surface of the busbars is not exposed to the passivation species. The surface of the busbars is therefore protected, which makes it possible to improve interconnection of the photovoltaic cells when forming the photovoltaic module.

In addition, by virtue of the presence of double busbars, the protection of the surfaces of the metallisations present on the faces of the photovoltaic cells 5 is reinforced (the passivation species reach even less the surface of the busbars 8A, 9A, 10A, 8B, 9B, 10B, 11A, 12A, 13A, 11B, 12B, 13B present on the faces 5A, 5B of the photovoltaic cells).

The absence of a passivation layer on the surface of the busbars guarantees the quality of the interconnection between the photovoltaic cells. The conductive glue for assembling the photovoltaic cells is positioned directly on the surface of the busbars. This facilitates the passage of electric charges between the photovoltaic cells in the photovoltaic module.

Also, by virtue of the positioning of the plurality of first busbars and of the plurality of second busbars, only the portions of the peripheral edge parallel to the busbars of each photovoltaic cell are visible and accessible from the outside of the stack. In other words, along these portions of the peripheral edge, the busbars (and in particular the busbars closest to these portions of the peripheral edge) isolate the core of each photovoltaic cell from the outside of the stack. This then ensures that, along these portions, only the peripheral edge of the photovoltaic cells and a small surface of the front and rear faces (at the portions of the peripheral edge transverse to the busbars) is exposed to the passivation species for deposition of the passivation layer.

In addition, the presence of pairs of busbars (especially in proximity to the portions of the peripheral edge) makes it possible to reinforce this effect of penetration barrier to passivating species.

Alternatively, the deposition of passivation layer can be carried out by other methods. For example, Physical Vapor Deposition (PVD) or Chemical Vapor Deposition (CVD) methods can be used.

Still alternatively, a chemical liquid deposition method can be used.

Still alternatively, plasma-based deposition methods can also be used. In such a case, the materials used, in particular for the support parts, have to be adapted to be conductive. For this, graphite can especially be used.

In practice, the two photovoltaic cells at the end of the stack are not used afterwards because they are either in direct contact with the support for the deposition of the passivation layer, or are subjected to the formation of the passivation layer on all of one of its faces. In a way, these two photovoltaic cells are sacrificed in the passivation process.

Furthermore, it is to be noted that it is possible that, along the portions 5C2, 5C4 of the peripheral edge 5C, a passivation layer may still be formed on part of the front and rear faces of each photovoltaic cell. However, given the arrangement of the photovoltaic cells in a stack, the width of the layer formed remains small (less than 100 μm along the portions 5C2, 5C4 of the peripheral edge 5C).

According to an alternative not represented, only the end busbars can have a double configuration. In other words, in this alternative and for example in relation to FIG. 1, the plurality of second busbars comprises only two busbars (the second busbars 8B, 10B) positioned in proximity to the portions 5C1, 5C3 of the peripheral edge of the photovoltaic cell.

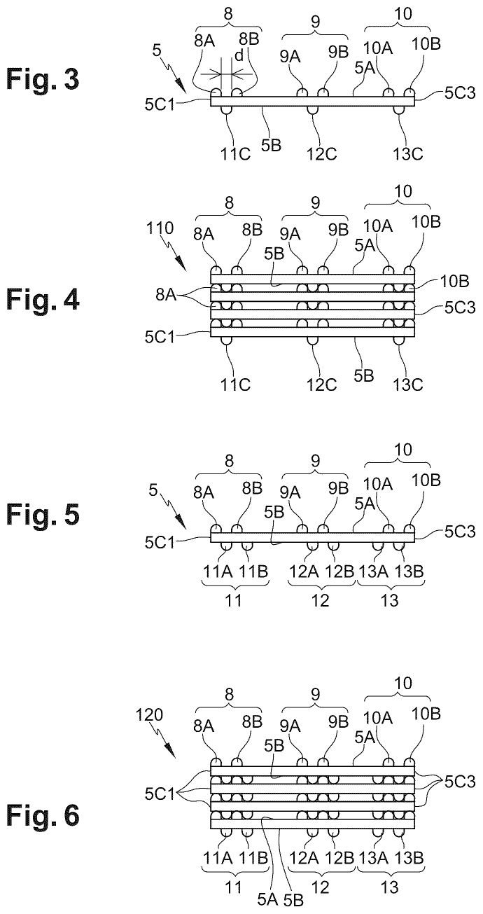

FIGS. 3 and 4 correspond to a second example of implementation of the passivation method in accordance with the invention.

The passivation method according to this second example comprises the same steps of providing the plurality of photovoltaic cells, stacking them and depositing a passivation layer as the first example of implementation. Thus, only the differences from this first example are described in detail hereinafter.

In this second example, each photovoltaic cell 5 is provided on one of its faces with the plurality of first busbars 8A, 9A, 10A and the plurality of second busbars 8B, 9B, 10B and on the other of its faces with a plurality of third busbars 11C, 12C, 13C.

As shown in FIGS. 3 and 4, the plurality of first busbars 8A, 9A, 10A and the plurality of second busbars 8B, 9B, 10B are formed on the front face 5A of the photovoltaic cell 5. In turn, the plurality of third busbars is formed on the opposite face, that is, on the rear face 5B of the photovoltaic cell 5.

In other words, in this second example, the photovoltaic cell 5 is provided, on one of its faces, with pairs of busbars 8, 9, 10 (as in the first example described previously) and, on the other of its faces, with a single series of third busbars 11C, 12C, 13C.

The specificity of this second example lies in the positioning of each third busbar 11C, 12C, 13C (on the rear face 5B of the photovoltaic cell 5) with respect to each pair 8, 9, 10 of busbars formed on the front face 5A of the photovoltaic cell 5.

As described in the first example, in each pair 8, 9, 10 of busbars, the first busbar 8A, 9A, 10A and the second busbar 8B, 9B, 10B are formed at a distance from each other. A space is therefore defined between the first busbar 8A, 9A, 10A and the second busbar 8B, 9B, 10B of each pair 8, 9, 10 of busbars.

In this second example, beneficially, each third busbar 11C, 12C, 13C of the plurality of third busbars is positioned facing the space defined between the first busbar 8A, 9A, 10A and the second busbar 8B, 9B, 10B of the pair 8, 9, 10 of busbars concerned. This positioning then makes it possible, during the stacking step described hereafter, to position each third busbar 11C, 12C, 13C of the plurality of third busbars of a photovoltaic cell 5 between the first busbar 8A, 9A, 10A and the second busbar 8B, 9B, 10B of the pair 8, 9, 10 of busbars concerned of an adjacent photovoltaic cell.

As described previously, beneficially according to an embodiment of the invention, the predetermined distance is, for example, in the order of the width of each busbar. In an embodiment, this predetermined distance is less than or equal to 100 μm. In an embodiment still, this predetermined distance is less than or equal to 50 μm. In other words, for each pair 8, 9, 10 of busbars, the second busbar 8B, 9B, 10B is positioned at a distance less than or equal to 100 μm (and in an embodiment 50 μm) from the associated first busbar 8A, 9A, 10A.

Thus, in this second example (FIGS. 3 and 4), before the stacking step, each photovoltaic cell 5 of the plurality of photovoltaic cells is provided, on the one hand, with the plurality of first busbars 8A, 9A, 10A and the plurality of second busbars 8B, 9B, 10B on one of its faces (here the front face 5A) and, on the other hand, with the plurality of third busbars 11C, 12C, 13C on the other of its faces (here the rear face 5B).

The passivation method then continues with the step of stacking the plurality of photovoltaic cells 5, each provided, on their front face, with the plurality of first busbars 8A, 9A, 10A and the plurality of second busbars 8B, 9B, 10B, and, on their rear face 5B, with the plurality of third busbars 11C, 12C, 13C. The stack 110 is then formed (visible in FIG. 4).

This stack 110 is here implemented vertically: the photovoltaic cells 5 are then superimposed on one another (as represented in FIG. 4). Alternatively, the stack can be made horizontally. In this case, the photovoltaic cells are positioned one after the other.

Beneficially according to an embodiment of the invention, each photovoltaic cell 5 is positioned so that, on the one hand, the plurality of first busbars 8A, 9A, 10A and the plurality of second busbars 8B, 9B, 10B of a photovoltaic cell and, on the other hand, the plurality of third busbars 11C, 12C, 13C of the adjacent photovoltaic cell 5 are placed between this photovoltaic cell 5 and the adjacent photovoltaic cell 5. In other words, in the stack 110, the photovoltaic cells 5 are arranged one after the other with the positioning of the plurality of first busbars 8A, 9A, 10A and the plurality of second busbars 8B, 9B, 10B of a photovoltaic cell 5 and the plurality of third busbars 11C, 12C, 13C of an adjacent photovoltaic cell between two adjacent photovoltaic cells 5.

In other words still, this arrangement is implemented so that the front face 5A of the photovoltaic cell 5 provided with the plurality of first busbars 8A, 9A, 10A and the plurality of second busbars 8B, 9B, 10B is positioned at a distance from the rear face 5B of the adjacent photovoltaic cell 5 provided with the plurality of third busbars 11C, 12C, 13C. For the record, the photovoltaic cells 5 considered in this second example all have the same configuration with the plurality of first busbars 8A, 9A, 10A and the plurality of second busbars 8B, 9B, 10B formed on the front face 5A and the plurality of third busbars 11C, 12C, 13C formed on the rear face 5B. The faces of the photovoltaic cells 5 are therefore not in contact with each other when stacked. This makes it possible especially to avoid degrading the interconnection metal zones, and hence electrical performance of the photovoltaic cells.

Beneficially here, and by virtue of the arrangement of the plurality of first busbars 8A, 9A, 10A, the plurality of second busbars 8B, 9B, 10B and the plurality of third busbars 11C, 12C, 13C, the stacking of the photovoltaic cells 5 is implemented so that that each third busbar 11C, 12C, 13C of the plurality of third busbars of a photovoltaic cell 5 is positioned between the first busbar 8A, 9A, 10A and the second busbar 8B, 9B, 10B of the pair 8, 9, 10 of busbars concerned of an adjacent photovoltaic cell. This configuration is visible in FIG. 4.

In addition to the benefits set forth for the first example described previously, the configuration of the second example is particularly beneficial because, by virtue of the arrangement, alternating and juxtaposed, of a pair of busbars 8, 9, 10 concerned and of a third busbar 11C, 12C, 13C, it makes it possible to reinforce the protection of the surfaces of the metallisations present on the faces of the photovoltaic cells 5 (the passivation species reach even less the surface of the busbars 8A, 9A, 10A, 8B, 9B, 10B, 11C, 12C, 13C present on the faces 5A, 5B of the photovoltaic cells).

In addition, this configuration (alternating and juxtaposed) also makes it possible to reinforce the barrier effect to the penetration of the passivation species used for deposition. Indeed, along each portion 5C1, 5C3 of the peripheral edge 5C, the three juxtaposed busbars thus form a triple barrier to the penetration of the passivation species used for deposition. This further ensures that, along the first portion 5C1 and the second portion 5C3 of the peripheral edge, only the peripheral edge 5C of the photovoltaic cells 5 is exposed to the passivation species for deposition of the passivation layer.

Furthermore, the positioning of each third busbar 11C, 12C, 13C between the first busbar 8A, 9A, 10A and the second busbar 8B, 9B, 10B of each pair 8, 9, 10 of busbars guarantees proper alignment of the photovoltaic cells 5 when they are stacked.

FIGS. 5 and 6 correspond to a third example of implementation of the passivation method according to the first embodiment of the invention.

The passivation method according to this third example comprises the same steps of providing, stacking and depositing a passivation layer as the first embodiment described previously. Therefore, only the differences from this first example of embodiment are described in detail hereinafter.

Thus, on the basis of what is described for the first example described previously, one of the faces (for example the front face) of each photovoltaic cell 5 is provided with the plurality of first busbars 8A, 9A, 10A and the plurality of second busbars 8B, 9B, 10B.

In this third example of implementation, each photovoltaic cell 5 is also provided, on its other face (here on the rear face 5B), with a plurality of fourth busbars 11A, 12A, 13A and a plurality of fifth busbars 11B, 12B, 13B.

In the same way as described previously, the fourth busbars 11A, 12A, 13A extend in parallel to each other and the fifth busbars 11B, 12B, 13B extend in parallel to each other. Thus, all the busbars of the plurality of fourth busbars and the plurality of fifth busbars extend in parallel to each other. Here, they extend in parallel to the first portion 5C1 and the third portion 5C3 of the peripheral edge 5C.

Thus, a plurality of other pairs 11, 12, 13 of busbars are formed. Each other pair 11, 12, 13 of busbars comprises a fourth busbar 11A, 12A, 13A from the plurality of fourth busbars and a fifth busbar 11B, 12B, 13B from the plurality of fifth busbars.

In practice, each fifth busbar 11B, 12B, 13B of the plurality of fifth busbars is formed at a predetermined distance d from the corresponding fourth busbar 11A, 12A, 13A of the plurality of fourth busbars. In other words, in each other pair 11, 12, 13 of busbars, the fifth busbar 11B, 12B, 13B is positioned at a distance (and at the same distance) from the corresponding fourth busbar 11A, 12A, 13A.

Beneficially according to an embodiment of the invention, the predetermined distance is, for example, in the order of the width of each busbar. In an embodiment, the predetermined distance is less than or equal to 100 μm. In an embodiment still, this predetermined distance is less than or equal to 50 μm. In other words, for each pair 11, 12, 13 of busbars, the fifth busbar 11B, 12B, 13B is positioned at a distance less than or equal to 100 μm (and in an embodiment 50 μm) from the fourth busbar 11A, 12A, 13A.

In other words, in this third example, the photovoltaic cell 5 is provided, on one of its faces (here the front face 5A), with a plurality of pairs 8, 9, 10 of busbars and, on the other of its faces (here the rear face 5B), with a plurality of other pairs 11, 12, 13 of busbars.

The specificity of this third example lies in the positioning of each other pair 11, 12, 13 of busbars with respect to the corresponding pair 8, 9, 10.

As described in the first example, in each pair 8, 9, 10 of busbars, the first busbar 8A, 9A, 10A and the second busbar 8B, 9B, 10B are formed at a distance from each other. A space is therefore defined between the first busbar 8A, 9A, 10A and the second busbar 8B, 9B, 10B of each pair 8, 9, 10 of busbars.

In this third example, beneficially, the fourth busbar 11A, 12A, 13A of each other pair 11, 12, 13 of busbars is positioned facing the space defined between the first busbar 8A, 9A, 10A and the second busbar 8B, 9B, 10B of the corresponding pair 8, 9, 10 of busbars.

Similarly, in each other pair 11, 12, 13 of busbars, the fourth busbar 11A, 12A, 13A and the fifth busbar 11B, 12B, 13B are formed at a distance from each other. A space is therefore defined between the fourth busbar 11A, 12A, 13A and the fifth busbar 11B, 12B, 13B of each other pair 11, 12, 13 of busbars. In this third example, the second busbar 8B, 9B, 10B of each pair 8, 9, 10 of busbars is therefore positioned facing the space defined between the fourth busbar 11A, 12A, 13A and the fifth busbar 11B, 12B, 13B of the other corresponding pair 11, 12, 13 of busbars.

This configuration then makes it possible, during the stacking step described hereafter, to position the fourth busbar of each other pair 11, 12, 13 of busbars of a photovoltaic cell 5 between the first busbar 8A, 9A, 10A and the second busbar 8B, 9B, 10B of the corresponding pair 8, 9, 10 of busbars of an adjacent photovoltaic cell 5.

In other words, as visible in FIG. 6, there is a positioning offset between the first busbar 8A, 9A, 10A and the second busbar 8B, 9B, 10B of each pair 8, 9, 10 of busbars (on the front face) and the fourth busbar 11A, 12A, 13A and the fifth busbar 11B, 12B, 13B of each other corresponding pair 11, 12, 13 of busbars (on the rear face).

The distance between the fourth busbar 11A, 12A, 13A and the fifth busbar 11B, 12B, 13B of each other pair 11, 12, 13 of busbars (on the rear face 5B) is for example identical to the distance between the first busbar 8A, 9A, 10A and the second busbar 8B, 9B, 10B of each corresponding pair 8, 9, 10 of busbars (on the front face 5A of the photovoltaic cell 5). Alternatively, it may of course be different.

The passivation method then continues with the step of stacking the plurality of photovoltaic cells 5 each provided, on their front face, with the plurality of first busbars 8A, 9A, 10A and the plurality of second busbars 8B, 9B, 10B, and, on their rear face 5B, with the plurality of fourth busbars 11A, 12A, 13A and the plurality of fifth busbars 11B, 12B, 13B. The stack 120 is then formed (visible in FIG. 6).

This stack 120 is here implemented vertically: the photovoltaic cells 5 are then superimposed on one another (as represented in FIG. 6). Alternatively, the stack can be made horizontally. In this case, the photovoltaic cells are positioned one after the other.

Beneficially according to an embodiment of the invention, each photovoltaic cell 5 is positioned so that, on the one hand, the plurality of first busbars 8A, 9A, 10A and the plurality of second busbars 8B, 9B, 10B of the front face 5A of a photovoltaic cell 5 and, on the other hand, the plurality of fourth busbars 11A, 12A, 13A and the plurality of fifth busbars 11B, 12B, 13B of the rear face 5B of the adjacent photovoltaic cell 5 are placed between this photovoltaic cell 5 and the adjacent photovoltaic cell 5. In other words, in the stack 120, the photovoltaic cells 5 are arranged one after the other with the positioning of the plurality of first busbars 8A, 9A, 10A and the plurality of second busbars 8B, 9B, 10B of the front face 5A of a photovoltaic cell 5 and of the plurality of fourth busbars 11A, 12A, 13A and of the plurality of fifth busbars 11B, 12B, 13B of the rear face 5B of an adjacent photovoltaic cell between these two adjacent photovoltaic cells 5.

In other words still, this arrangement is implemented such that the front face 5A of the photovoltaic cell 5 provided with the plurality of first busbars 8A, 9A, 10A and the plurality of second busbars 8B, 9B, 10B is positioned at a distance from the rear face 5B of the adjacent photovoltaic cell 5 provided with the plurality of fourth busbars 11A, 12A, 13A and the plurality of fifth busbars 11B, 12B, 13B. For the record, the photovoltaic cells 5 considered in this fifth example all have the same configuration with the plurality of first busbars 8A, 9A, 10A and the plurality of second busbars 8B, 9B, 10B formed on the front face 5A and the plurality of fourth busbars 11A, 12A, 13A and the plurality of fifth busbars 11B, 12B, 13B formed on the rear face 5B. The faces of the photovoltaic cells 5 are therefore not in contact with each other when stacked. This makes it possible especially to avoid degrading the interconnection metal zones, and hence the electrical performance of the photovoltaic cells.

Beneficially here, and by virtue of the arrangement, on the one hand, of the plurality of first busbars 8A, 9A, 10A and the plurality of second busbars 8B, 9B, 10B on the front face 5A and, on the other hand, of the plurality of fourth busbars 11A, 12A, 13A and the plurality of fifth busbars 11B, 12B, 13B on the rear face 5B, the stack of photovoltaic cells 5 is implemented so that each fourth busbar 11A, 12A, 13A of the plurality of fourth busbars of a photovoltaic cell 5 is positioned between the first busbar 8A, 9A, 10A and the second busbar 8B, 9B, 10B of the pair 8, 9, 10 of busbars concerned of an adjacent photovoltaic cell 5. This arrangement then results in each second busbar 8B, 9B, 10B of the plurality of second busbars of a photovoltaic cell 5 being positioned between the fourth busbar 11A, 12A, 13A and the fifth busbar 11B, 12B, 13B of the pair 11, 12, 13 of busbars concerned of an adjacent photovoltaic cell. This configuration is visible in FIG. 6.

In addition to the benefits set forth for the first example described previously, the configuration of the third example is particularly beneficial because, by virtue of the arrangement, alternating and juxtaposed, of the busbars of the pairs 8, 9, 10 of busbars and of the other pairs 11, 12, 13 of busbars, it makes it possible to reinforce the protection of the surfaces of the metallisations present on the faces of the photovoltaic cells 5 (the passivation species reach even less the surface of the busbars 8A, 9A, 10A, 8B, 9B, 10B, 11A, 12A, 13A, 11B, 12B, 13B present on the faces 5A, 5B of the photovoltaic cells).

In addition, this configuration (alternating and juxtaposed) also makes it possible to reinforce the barrier effect to the penetration of the passivation species used for deposition. Along each portion 5C1, 5C3 of the peripheral edge 5C, the four juxtaposed busbars therefore form a quadruple barrier to the penetration of the passivation species used for deposition. This further ensures that, along the first portion 5C1 and the second portion 5C3 of the peripheral edge, only the peripheral edge 5C of the photovoltaic cells 5 is exposed to the passivation species for deposition of the passivation layer.

Furthermore, the positioning of each fourth busbar 11A, 12A, 13A between the first busbar 8A, 9A, 10A and the second busbar 8B, 9B, 10B of each pair 8, 9, 10 of busbars guarantees proper alignment of the photovoltaic cells 5 when they are stacked.

FIGS. 7 to 10 relate to a second embodiment of the passivation method in accordance with the invention. This second embodiment finds a particularly beneficial application for sub-cells with a smaller surface area (according to the format commonly known as “shingle”).

In this second embodiment, each photovoltaic cell 6 considered is provided, on one of its faces, with at least one first busbar 20A, and, on the other of its faces, with a second busbar 22A.

As represented in FIG. 7, the first busbar 20A extends in parallel to the first portion 6C1 of the peripheral edge 6C of the photovoltaic cell 6. The first busbar 20A is here positioned on the front face 6A of the photovoltaic cell 6.

The second busbar 22A extends in parallel to the second portion 6C3 of the peripheral edge 6C. The second busbar 22A is positioned on the face opposite to the one provided with the first busbar 20A. Here, the second busbar 22A is therefore positioned on the rear face 6B of the photovoltaic cell 6.

Here, due to the process for manufacturing the photovoltaic cell 6, the first busbar 20A and the second busbar 22A are each formed (here each on a face 6A, 6B of the photovoltaic cell 6) in proximity to the peripheral edge 6C.

Thus, each photovoltaic cell 6 considered in the second embodiment of the passivation method comprises, at least, on one of its faces 6A, 6B, the first busbar 20A positioned in proximity to the first portion 6C1 of the peripheral edge 6C and, on the opposite face 6A, 6B, the second busbar 22A positioned in proximity to the second portion 6C3 of the peripheral edge 6C.

FIGS. 7 and 8 correspond to a first example of implementation of the passivation method according to the second embodiment.

The passivation method according to this first example of the second embodiment comprises the same steps of providing the plurality of photovoltaic cells, stacking them and depositing a passivation layer as the first example of implementation of the first embodiment described previously. Therefore, only the differences from this first example of the first embodiment are described in detail hereinafter.

In this first example of implementation of the second embodiment, all the photovoltaic cells 6 of the plurality of photovoltaic cells are each provided, on one of their faces, with the first busbar 20A (here on the front face 6A) and, on the opposite face (here the rear face 6B), with the second busbar 22A.

In practice, these photovoltaic cells 6 (with the first busbar 20A on the front face 6A and the second busbar 22A on the rear face 6B) are obtained, for example, by cutting conventional full-size photovoltaic cells. Cutting is performed in such a way that each sub-cell obtained generally comprises a single busbar (for example here the first busbar 20A on the front face).

Each photovoltaic cell 6 is then obtained by forming the second busbar 22A on the face opposite to the face comprising the first busbar 20A (here the rear face 6A). In other words, each photovoltaic cell 6 is thus obtained by adding an additional busbar (here the second busbar 22A) on the face opposite to the face of the sub-cell (obtained by cutting) on which the first busbar 20A is located. This is implemented, for example, prior to the first step of providing the photovoltaic cells 6.

The passivation method then comprises the step of stacking the plurality of photovoltaic cells 6, provided with their first busbar 20A on the front face 6A and their second busbar 22A on the rear face 6B. A stack 200 is represented in FIG. 8.

This stack 200 is for example implemented vertically: the photovoltaic cells 6 are then superimposed on one another (as represented in FIG. 8). Alternatively, the stack may be made horizontally. In this case, the photovoltaic cells are positioned one after the other.

Beneficially according to an embodiment of the invention, each photovoltaic cell 6 is positioned so that the first busbar 20A of the photovoltaic cell 6 concerned and the second busbar 22A of the adjacent photovoltaic cell 6 are placed between this photovoltaic cell 6 and the adjacent photovoltaic cell 6. In other words, in the stack 200, the photovoltaic cells 6 are arranged one after the other with the positioning of the first busbar 20A of a photovoltaic cell and the positioning of the second busbar 22A of the adjacent photovoltaic cell between these photovoltaic cells 6. This arrangement is implemented such that the front face 6A of the photovoltaic cell 6 provided with the first busbar 20A is positioned at a distance from the rear face 6B of the adjacent photovoltaic cell 6 provided with the second busbar 22B. The faces of the photovoltaic cells 6 are therefore not in contact with each other when stacked.

In this stacking step, the first busbar 20A of the photovoltaic cell concerned and the second busbar 22B of the adjacent photovoltaic cell are therefore positioned in direct contact with the opposite face of the facing photovoltaic cell 6. In other words, considering a first photovoltaic cell and a second photovoltaic cell, the first busbar of the first photovoltaic cell is in direct contact with the rear face of the second photovoltaic cell and the second busbar of the second photovoltaic cell is in direct contact with the front face of the first photovoltaic cell.

In practice, this stacking step comprises, for example, a step of rotating the photovoltaic cell 6 to be stacked so as to ensure direct contact between the first busbar 20A of the photovoltaic cell concerned and the second busbar 22B of the adjacent photovoltaic cell. In other words, the photovoltaic cells 6 are here stacked without direct contact between the first busbar 20A of one photovoltaic cell and the second busbar 22A of the adjacent photovoltaic cell.

The rotation performed here is, for example, a rotation through an angle of 180 degrees.

This configuration is particularly beneficial because it enables the photovoltaic cells 6 to be stacked without the front and rear faces of each photovoltaic cell 6 being subjected to stress, or the metallisations being in contact with each other. This avoids degrading electrical performance.

In addition, by virtue of the presence of the first busbar 20A and the second busbar 22A and their positioning relative to the peripheral edge 6C, when the photovoltaic cells 6 are stacked, only the peripheral edge 6C (along the first portion 6C1 and the second portion 6C3 of the peripheral edge 6C) of each photovoltaic cell 6 is visible and accessible from the outside of the stack 200. In other words, the first busbar 20A and the second busbar 22A isolate, along the first portion 6C1 and the second portion 6C3 of the peripheral edge 6C, the core of each photovoltaic cell 6 from the outside of the stack 200. This then ensures that, along the first portion 6C1 and the second portion 6C3 of the peripheral edge, only the peripheral edge 6C of the photovoltaic cells 6 is exposed to the passivation species for the deposition of the passivation layer (as previously indicated, this deposition of the passivation layer is performed in the manner described in the first example of implementation of the first embodiment).

As an alternative to this first example, before the stacking step, there may be provided a step of forming, on each photovoltaic cell, a protective element on each of the front and rear faces. This protective element has, for example, the same shape and dimensions as a busbar and is formed on each of the front and rear faces, along the portion of the peripheral edge not having busbars.

In other words, here, a first protective element is formed, for example, on the front face of each photovoltaic cell, facing the second busbar present on the rear face, and a second protective element is formed on the rear face, facing the first busbar present on the front face.

The protective element is formed, for example, of an electrically conductive metal material. It is, for example, aluminium.

When the photovoltaic cells are stacked, the first busbar and second busbar are no longer in direct contact with the face of the adjacent cell facing the concerned cell, but with the protective element formed on the face facing it. This makes it possible to avoid direct contact with the face concerned of the photovoltaic cell, and therefore to avoid degrading the electrical performance of the cell (because in the case of sub-cells, the ends of the front and rear faces, without busbars, are potentially provided with metal interconnection zones).

FIGS. 9 and 10 correspond to a second example of implementation of the passivation method according to the second embodiment.

The passivation method according to this second example comprises the same steps of providing the plurality of photovoltaic cells, stacking them and depositing a passivation layer as the first example of implementation. Therefore, only the differences from this first example are described in detail below.

In this second example of implementation, each photovoltaic cell 6 also comprises a third busbar 20B and a fourth busbar 22B. The third busbar 20B is formed on the same face as that provided with the first busbar 20A. The fourth busbar 22B is formed on the same face as that provided with the second busbar 22B. In other words, as is visible in FIG. 9, the front face 6A of each photovoltaic cell 6 is here provided with the first busbar 20A and the third busbar 20B and the rear face 6B is here provided with the second busbar 22A and the fourth busbar 22B.

As is also visible in FIG. 9, the third busbar 20B is formed in parallel to the first busbar 20A and the fourth busbar 22B is formed in parallel to the second busbar 22A.

In practice, the third busbar 20B is formed at another predetermined distance from the first busbar 20A. In turn, the fourth busbar 22B is formed at this other predetermined distance from the second busbar 22A. In other words, the third busbar 20B and the fourth busbar 22B are respectively positioned at a distance (and at the same distance) from the first busbar 20A and the second busbar 20B.

Beneficially according to an embodiment of the invention, the other predetermined distance is, for example, in the order of the width of each busbar. In an embodiment, the other predetermined distance is less than or equal to 100 μm. In an embodiment still, the other predetermined distance is less than or equal to 50 μm. In other words, the third busbar 20B is positioned at a distance less than or equal to 100 μm (and in an embodiment 50 μm) from the first busbar 20A and the fourth busbar 22B is positioned at a distance less than or equal to 100 μm (and in an embodiment 50 μm) from the second busbar 22A.

For the rest, the third busbar 20B and the fourth busbar 22B have the same characteristics as those previously described for the first busbar 20A and the second busbar 22A (in particular relating to width, height and formation method).

Thus, each photovoltaic cell 6 considered in this second example comprises, on one of its faces (here the front face 6A), the first busbar 20A positioned in proximity to the first portion 6C1 of the peripheral edge 6C and the third busbar 20B which extends in proximity to the first busbar 20A, and, on the other of its faces (here the rear face 6B) the second busbar 22A positioned in proximity to the second portion 6C3 of the peripheral edge 6C and the fourth busbar 22B which extends in proximity to the second busbar 8B.

The passivation method then continues with the step of stacking the plurality of photovoltaic cells 6, each provided, on their front face 6A, with their first busbar 20A and their third busbar 20B and, on their rear face 6B, with their second busbar 22A and their fourth busbar 22B (a stack 210 is visible in FIG. 10).

This stack 210 is for example implemented vertically: the photovoltaic cells 6 are then superimposed on one another (as represented in FIG. 10). Alternatively, the stack may be made horizontally. In this case, the photovoltaic cells are positioned one after the other.

Beneficially according to an embodiment of the invention, each photovoltaic cell 6 is positioned so that the first busbar 20A and the third busbar 20B of the photovoltaic cell 6 concerned and the second busbar 22A and the fourth busbar 22B of the adjacent photovoltaic cell 6 are placed between this photovoltaic cell 6 and the adjacent photovoltaic cell 6. In other words, in the stack 210, the photovoltaic cells 6 are arranged one after the other with the positioning of the first busbar 20A and the third busbar 20B of a photovoltaic cell and the second busbar 22A and the fourth busbar 22B of the adjacent photovoltaic cell between two adjacent photovoltaic cells.

This arrangement is implemented such that the front face 6A of the photovoltaic cell 6 provided with the first busbar 20A and the third busbar 20B is positioned at a distance from the rear face 6B of the adjacent photovoltaic cell 6 provided with the second busbar 22A and the fourth busbar 22B. For the record, the photovoltaic cells 6 considered in this second example all have the same configuration with a first busbar 20A and a third busbar 20B formed on the front face 6A and a second busbar 22A and a fourth busbar 22B formed on the rear face 6B. The faces of the photovoltaic cells 6 are therefore not in contact with each other when stacked.

In this stacking step, the first busbar 20A and the third busbar 20B of the photovoltaic cell concerned are therefore positioned in direct contact with the rear face of the adjacent cell, and the second busbar 22A and the fourth busbar 22B of this adjacent photovoltaic cell are positioned in direct contact with the front face of the photovoltaic cell 6 concerned.

In addition to the benefits previously set forth for the first example, the configuration of the second example is particularly beneficial because, by virtue of the presence of the third and fourth busbars, it makes it possible to reinforce the protection of the surfaces of the metallisations present on the faces of the photovoltaic cells 6 (the passivation species reach even less the surface of the busbars 20A, 20B, 22A, 22B present on the faces 6A, 6B of the photovoltaic cells).

In addition, this configuration with a double busbar in proximity to the portions 6C1, 6C3 of the peripheral edge makes it possible to reinforce the barrier effect to the penetration of the passivation species used for deposition of the thin layer. The first busbar 20A and the third busbar 20B, on the one hand, and the second busbar 22A and the fourth busbar 22B, on the other hand, therefore form a double barrier to the penetration of the passivation species used for deposition, along the first portion 6C1 and the second portion 6C3 of the peripheral edge 6C. This further ensures that, along the first portion 6C1 and the second portion 6C3 of the peripheral edge, only the peripheral edge 6C of the photovoltaic cells 6 is exposed to the passivation species for deposition of the passivation layer.

Alternatively, as described for the first example of the second embodiment of the passivation method, before the stacking step, there may be provided the formation of protective elements on each of the front and rear faces, along the portion of the peripheral edge not having busbars.

These protective elements are formed, for example, on the front face of each photovoltaic cell, facing the second busbar and the fourth busbar and, on the rear face of the photovoltaic cell, facing the first busbar and the third busbar.

By virtue of these protective elements, when the photovoltaic cells are stacked, the busbars are no longer in direct contact with the face of the adjacent cell facing the face provided with the busbars but with the protective element formed on the face facing it. This avoids direct contact with the face concerned of the photovoltaic cell, and therefore avoids degrading the electrical performance of the cell.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. A method for passivating photovoltaic cells comprising:
providing a plurality of photovoltaic cells, each photovoltaic cell comprising a front face, intended to be exposed to incident radiation, a rear face opposite to the front face and a peripheral edge connecting the front face and the rear face, each photovoltaic cell being provided, on the front face or the rear face, with a plurality of first interconnection conductor tracks and a plurality of second interconnection conductor tracks, the plurality of second interconnection conductor tracks extending in parallel to the plurality of first interconnection conductor tracks, a plurality of pairs of interconnection conductor tracks being formed, each pair of interconnection conductor tracks being formed, each pair of interconnection conductor tracks comprising a first interconnection conductor track from the plurality of first interconnection conductor tracks and a second interconnection conductor track from the plurality of second interconnection conductor tracks,
stacking the plurality of photovoltaic cells, the plurality of first interconnection conductor tracks and the plurality of second interconnection conductor tracks of each photovoltaic cell being positioned between the photovoltaic cell concerned and an adjacent photovoltaic cell in such a way that the face of the photovoltaic cell provided with the plurality of first interconnection conductor tracks and the plurality of second interconnection conductor tracks is positioned at a distance from the face of the adjacent photovoltaic cell facing said face of the photovoltaic cell provided with the plurality of first interconnection conductor tracks and the plurality of second interconnection conductor tracks, and
depositing a passivation layer onto the peripheral edge of the photovoltaic cells of the plurality of photovoltaic cells by injecting at least one passivation species.

2. The passivation method according to claim 1, wherein, for each pair of interconnection conductor tracks, the first interconnection conductor track from the plurality of first interconnection conductor tracks and the second interconnection conductor track from the plurality of second interconnection conductor tracks are spaced apart by a predetermined distance of less than 100 micrometres.

3. The passivation method according to claim 1, wherein, during the stacking, the photovoltaic cells are positioned in such a way that the plurality of first interconnection conductor tracks and the plurality of second interconnection conductor tracks are in direct contact with the face of the adjacent photovoltaic cell facing said face of the photovoltaic cell provided with the plurality of first interconnection conductor tracks and the plurality of second interconnection conductor tracks.

4. The passivation method according to claim 1, wherein each photovoltaic cell of the plurality of photovoltaic cells comprises a plurality of electrodes positioned transversally to the plurality of first interconnection conductor tracks and the plurality of second interconnection conductor tracks, each first interconnection conductor track from the plurality of first interconnection conductor tracks and each second interconnection conductor track from the plurality of second interconnection conductor tracks having a width greater than or equal to the width of each electrode of the plurality of electrodes.

5. The passivation method according to claim 1, wherein each photovoltaic cell also comprises a plurality of third interconnection conductor tracks, the plurality of third interconnection conductor tracks being formed on the face opposite to the face provided with the plurality of first interconnection conductor tracks and the plurality of second interconnection conductor tracks.

6. The passivation method according to claim 5, wherein, during the stacking, the photovoltaic cells are positioned such that each third interconnection conductor track from the plurality of third interconnection conductor tracks of a photovoltaic cell is placed between a first interconnection conductor track and a second interconnection conductor track of a corresponding pair of interconnection conductor tracks of the adjacent photovoltaic cell, each third interconnection conductor track being in direct contact with the face of the adjacent photovoltaic cell on which the first interconnection conductor track concerned and the second interconnection conductor track concerned are formed.

7. The passivation method according to claim 5, wherein each photovoltaic cell also comprises a plurality of fourth interconnection conductor tracks and a plurality of fifth interconnection conductor tracks, the plurality of fifth interconnection conductor tracks extending in parallel to the plurality of fourth interconnection conductor tracks, the plurality of fourth interconnection conductor tracks and the plurality of fifth interconnection conductor tracks being formed on the face opposite to the face provided with the plurality of first interconnection conductor tracks and the plurality of second interconnection conductor tracks, the plurality of fourth interconnection conductor tracks being positioned facing the plurality of first interconnection conductor tracks and the plurality of fifth interconnection conductor tracks being positioned facing the plurality of second interconnection conductor tracks.

8. A method for passivating photovoltaic cells comprising:
providing a plurality of photovoltaic cells, each photovoltaic cell comprising a front face, intended to be exposed to incident radiation, a rear face opposite to the front face and a peripheral edge connecting the front face and the rear face, each photovoltaic cell being provided, on the front face, with a first interconnection conductor track positioned in parallel to a first portion of the peripheral edge, each photovoltaic cell being provided, on the rear face, with a second interconnection conductor track positioned in parallel to a second portion of the peripheral edge, the first portion of the peripheral edge and the second portion of the peripheral edge (6C) being parallel to each other,
stacking the plurality of photovoltaic cells, the first interconnection conductor track and the second interconnection conductor track of each photovoltaic cell being positioned between the photovoltaic cell concerned and an adjacent photovoltaic cell in such a way that the front face of the photovoltaic cell provided with the first interconnection conductor track is positioned at a distance from the rear face of the adjacent photovoltaic cell provided with the second interconnection conductor track, and
depositing a passivation layer onto the peripheral edge of the photovoltaic cells of the plurality of photovoltaic cells by injecting at least one passivation species, the first interconnection conductor track (20A) and the second interconnection conductor track forming a penetration barrier to the passivation species so that the passivation layer covers the peripheral edge of each photovoltaic cell.

9. The passivation method according to claim 8, wherein, during the stacking, the photovoltaic cells are positioned in such a way that the first interconnection conductor track and the second interconnection conductor track are in direct contact with the face of the adjacent photovoltaic cell facing the face of the photovoltaic cell provided with the first interconnection conductor track and the second interconnection conductor track.

10. The passivation method according to claim 8, wherein each photovoltaic cell comprises a third interconnection conductor track and a fourth interconnection conductor track, the third interconnection conductor track being formed on the face provided with the first interconnection conductor track, in parallel with the first interconnection conductor track, the fourth interconnection conductor track being formed on the face provided with the second interconnection conductor track, in parallel with the second interconnection conductor track, the third interconnection conductor track being formed at a predetermined distance from the first interconnection conductor track and the fourth interconnection conductor track being formed at said predetermined distance from the second interconnection conductor track.

11. The passivation method according to claim 10, wherein the predetermined distance is less than 100 micrometres.
